(19) United States
(12) Patent Application Publication
(10) Pub. No.: US 2012/0017983 A1
(43) Pub. Date: Jan. 26, 2012

(54) BUFFER LAYER FORMATION

(76) Inventor: Markus E. Beck, Scotts Valley, CA (US)

(21) Appl. No.: 13/190,086

(22) Filed: Jul. 25, 2011

Related U.S. Application Data
(60) Provisional application No. 61/367,121, filed on Jul. 23, 2010.

(51) Int. Cl. H01L 31/032; C23C 16/455; C23C 16/30; H01L 31/18; H01L 31/0224

(52) U.S. Cl. 136/256; 438/95; 136/262; 118/724; 257/E31.027

(57) ABSTRACT

Manufacturing a photovoltaic device can include a vapor transport deposition process.

### CLAIM FOR PRIORITY

This application claims priority under 35 U.S.C. §119(e) to Provisional U.S. Patent Application Ser. No. 61/367,121, filed on Jul. 23, 2010, which is hereby incorporated by reference.

### TECHNICAL FIELD

This invention relates to manufacturing a photovoltaic device with a vapor transport deposition process.

### BACKGROUND

Manufacturing a photovoltaic device can include depositing a semiconductor layer. Some available deposition techniques (e.g. sputtering, evaporation) are line-of-sight depositions. As a result, these deposition techniques can be problematic for conformal coating of rough surface.

### DESCRIPTION OF DRAWINGS

FIG. 1 is a schematic of a deposition system.

FIG. 2 is a partially broken-away sectional view taken through a distributor of the system along the direction of line 2-2 in FIG. 1.

FIG. 3 is a sectional view through the distributor taken along the direction of line 3-3 in FIG. 2.

FIG. 4 is a bottom plan view taken along the direction of line 4-4 of FIG. 2 to illustrate a varying size slit opening of a shroud of the system.

FIG. 5 is a view of a material supply.

FIG. 6 is a view of a material supply.

FIG. 7 is a schematic of a two stage deposition system.

FIG. 8 is a flowchart showing the steps in the process of forming a buffer layer.

FIG. 9 is a schematic of a photovoltaic device having multiple semiconductor layers.

### DETAILED DESCRIPTION

Photovoltaic devices can include multiple layers formed on a substrate (or superstrate). For example, a photovoltaic device can include a conducting layer, a semiconductor absorber layer, a buffer layer, a semiconductor window layer, and a transparent conductive oxide (TCO) layer, formed in a stack on a substrate. Each layer may in turn include more than one layer or film. For example, the semiconductor window layer and semiconductor absorber layer together can be considered a semiconductor layer. The semiconductor absorber layer can include copper-indium-gallium-(di)selenide (CIGS). The semiconductor layer can include a first film created (for example, formed or deposited) on the TCO layer and a second film created on the first film. Additionally, each layer can cover all or a portion of the device and/or all or a portion of the layer or substrate underlying the layer. For example, a “layer” can mean any amount of any material that contacts all or a portion of a surface.

Manufacturing a photovoltaic device can include depositing a semiconductor layer. For example, in manufacturing CIGS-based photovoltaic (PV) device, a buffer layer can be deposited by chemical bath deposition (CBD). Layers of In₂S₃, ZnS, or ZnSe can be deposited by various means. However, some available deposition techniques (e.g. sputtering, evaporation) are line-of-sight depositions. As a result, these deposition techniques can be problematic for conformal coating of a rough surface. A vapor transport deposition process and related deposition system are developed to achieve better results.

The present invention addresses aspects of manufacturability as well as a novel concept to deposit a semiconductor layer, such as In₂S₃, for applications which might include, but are not limited to, CIGS devices. Rather than depositing the compound layer via evaporation of its constituent elements In and S or directly evaporating from the compound onto the substrate, a vapor transport assisted growth process is developed.

In₂S₃ melts at 1050° C. and sublimes at lower temperatures to a vapor of In₂S and S₂. At the same time, the resulting evaporated pure In₂S₃ films result in an optical bandgap of approx. 2.0-2.2 eV. For use in PV devices, a larger bandgap is preferable in order to increase the device generated photocurrent. Controlled addition of oxygen can widen the direct optical band gap up to potentially that of In₂O₃ (3.6 eV).

Using an oxygen diluted transport gas in a vapor transport deposition (VTD) process can allow for partial oxidation and transport of the sublimed In₂S₃ vapor to the heated substrate for subsequent film growth. By practicing the composition and associated bandgap modification in the In-chalcogenide material system and their applications as buffer layers in CIGS devices, the films can be manufactured in the full bandgap range from In₂Se₃ to In₂O₃—i.e. In₂(O,S,Se)₃. However, due to the tendencies of chalcogenide displacement/stability of the individual chalcogenides, it is preferable to start with In₂Se₃ and facilitate the growing film to react with S vapor and O₂ in reactive mode rather than in the transport gas.

In some embodiments, a further implementation of VTD for buffer layers in CIGS devices is the formation of ZnS, ZnSe, ZnO, and Zn (O,S,Se). The sublimation temperature of ZnS is about 1180° C. while ZnSe sublimation has been reported in the range of 850-1200° C. The same approach as has been described above in the case of In-based chalcogenide buffer films can be taken to prepare Zn(O,S,Se) layers via VTD, resulting in a tunable bandgap range of 2.67 to 3.7 eV.

In some embodiments, in a two step VTD process, VTD of In₂(O,S,Se)₃ and Zn(O,S,Se) can be combined to grade the buffer layer in composition and bandgap via both metal and chalcogenide content.

In one aspect, a method of manufacturing a photovoltaic device can include forming a semiconductor absorber layer adjacent to a substrate. The semiconductor absorber layer can include copper indium gallium diselenide. The method can include heating a deposition material to form a deposition material vapor. The deposition material can include a metal chalcogenide. The method can include transporting the deposition material vapor to a deposition chamber with a transport gas through a delivery pipe. The method can include forming a buffer layer including the deposition material adjacent to the semiconductor absorber layer.

The method can include forming a conducting layer adjacent to the substrate before forming the semiconductor absorber layer adjacent to the substrate. The method can include forming a transparent conductive oxide layer adjacent to the buffer layer. The method can include forming a semiconductor window layer adjacent to the buffer layer before forming a transparent conductive oxide layer adjacent to the buffer layer. The deposition material can include indium sulfide. The deposition material can include an indium chalcogenide. The deposition material can include indium selenide. The deposition material can include zinc sulfide. The deposition material can include a zinc chalcogenide. The deposition material can include zinc selenide. The step of heating the deposition material can occur in an environment including oxygen.

The buffer layer further can include oxygen. The step of heating the deposition material can include heating the deposition material to a temperature greater than about 800 degrees C. The step of heating the deposition material can include heating the deposition material to a temperature greater than about 1000 degrees C. The method can include distributing the deposition material vapor evenly over the width of the substrate. The method can include mixing the deposition material vapor and the transport gas to facilitate the reaction between the vapor and the transport gas before the vapor exits the distributor. The method can include mixing the deposition material vapor and the transport gas to facilitate the reaction between the vapor and the transport gas after the vapor exits the distributor. The method can include heating the delivery pipe. The transport gas can include helium.

In another aspect, a vapor transport deposition system for manufacturing a photovoltaic device can include a deposition material source including a deposition material. The deposition material can include a material including indium or zinc. The system can include a heater to heat the deposition material into a deposition material vapor. The system can include a structure including a substrate, a conducting layer, and a semiconductor absorber layer. The semiconductor absorber layer can include copper indium gallium diselenide. The system can include a transport gas source which can transport the deposition material vapor. The system can include a delivery pipe which can deliver the transport gas and deposition material vapor to a position adjacent to the structure, resulting in the deposition material vapor being deposited adjacent to the semiconductor absorber layer to form a buffer layer.

The delivery pipe can be configured to mix the vapor and the transport gas and further facilitate the reaction between the vapor and the transport gas. The system can include a distributor in the deposition chamber for evenly distributing the vapor over the width of the substrate. The distributor can be configured to mix the vapor and the transport gas and further facilitate the reaction between the vapor and the transport gas. The system can include a conveyor for conveying a substrate adjacent to the distributor for deposition of the vapor as a layer on the substrate.

The deposition material can include indium sulfide. The deposition material can include an indium chalcogenide. The deposition material can include indium selenide. The deposition material can include zinc sulfide. The deposition material can include a zinc chalcogenide. The deposition material can include zinc selenide. The transport gas can include helium. The transport gas can include oxygen. The transport gas can include a mixture of helium and oxygen.

In another aspect, a method of depositing a material on a substrate can include heating a deposition material to form a deposition material vapor. The deposition material can include indium or zinc. The method can include transporting the deposition material vapor to a deposition chamber with a transport gas through a delivery pipe. The method can include forming a layer comprising the deposition material adjacent to the substrate. The deposition material can include indium sulfide. The deposition material can include an indium chalcogenide. The deposition material can include indium selenide. The deposition material can include zinc sulfide. The deposition material can include a zinc chalcogenide. The deposition material can include zinc selenide. The method can include reacting the deposition material vapor with oxygen present in the deposition chamber environment.

In another aspect, a photovoltaic device can include a substrate, a semiconductor absorber layer including copper indium gallium diselenide adjacent to the substrate, and a buffer layer including a metal chalcogenide adjacent to the semiconductor absorber layer. The photovoltaic device can include a conducting layer between the substrate and the semiconductor absorber layer. The photovoltaic device can include a transparent conductive oxide layer adjacent to the buffer layer. The photovoltaic device can include a semiconductor window layer between the buffer layer and the transparent conductive oxide layer. The buffer layer can include an indium chalcogenide. The buffer layer can include a zinc chalcogenide. The buffer layer can include oxygen.

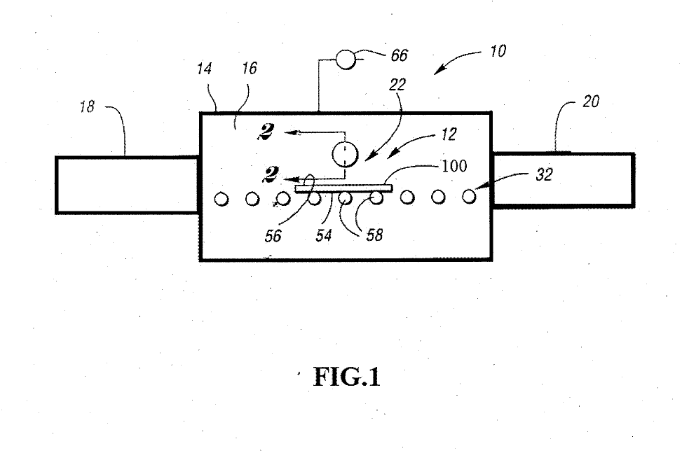

Referring to FIG. 1, deposition system 10 can include apparatus 12. Deposition system 10 processes glass substrate 100 for deposition of a semiconductor material, such as In₂S₃. In other embodiments, other substrates and deposition materials can also be utilized. For example, other materials can include In₂Se₃, ZnS, or ZnSe. The deposition can take place on metal substrates such as foils. In addition, it may be possible to deposit materials with high vapor pressures at moderate temperatures such as Zn or Pb, or any other suitable material.

As shown in FIG. 1, deposition system 10 can include housing 14 defining deposition chamber 16 in which a semiconductor material is deposited on glass substrate 100. Housing 14 includes entry station 18 and exit station 20. These entry and exit stations 18 and 20 can be constructed as load locks or as slit seals through which glass substrate 100 enter and exit deposition chamber 16. Housing 14 can be heated in any suitable manner. Deposition chamber 16 can be maintained at a temperature of 200° to 700° C., 500° to 800° C., 500° to 1100° C., or any suitable value, and glass substrate 100 can be heated during the processing to a slightly lower temperature of about 100° to 650° C., 300° to 750° C., or 300° to 850° C., or any suitable value.

Referring to FIGS. 1 through 3, apparatus 12 can include distributor 22 having electrically conductive permeable member 24. Permeable member 24 can be in a tubular shape having an elongated construction. Tubular permeable member 24 can be heated, which can be performed by electrical connections 26 at its opposite ends 28 and application of a voltage along the length of the member. This voltage causes an electrical current to flow along the length of tubular permeable member 24 so as to provide electrical heating thereof during the processing. Tubular permeable member 24 can be heated to maintain a temperature of about 800° to 1200° C. At least one material supply 30 of apparatus 12 can be provided for introducing a carrier gas and a semiconductor material into tubular permeable member 24 for heating to provide a vapor that passes outwardly through the tubular permeable member during the processing. Conveyor 32 of the apparatus conveys glass substrate 100 adjacent to distributor 22 for deposition of the vapor on the substrate as a semiconductor layer.

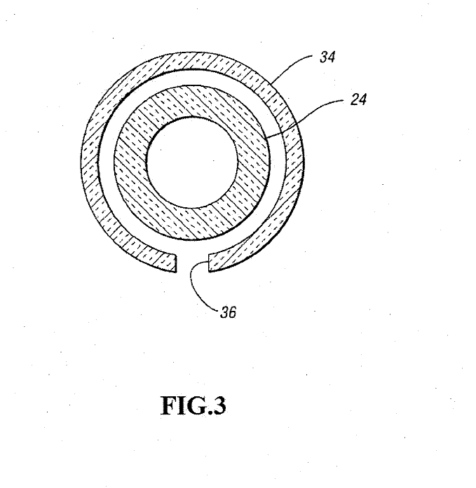

In some embodiments, tubular permeable member 24 can be made of silicon carbide although it could also be made of permeable carbon or any other permeable material that is preferably electrically conductive to provide the heating in the manner disclosed. Furthermore, distributor 22 can include shroud 34 of a generally tubular shape that receives the tubular permeable member 24 shown in FIG. 3. Shroud 34 can guide the vapor around the exterior of the tubular permeable member 24 and has opening 36 through which the vapor passes for the deposition of the semiconductor layer on glass substrate 100. More specifically, shroud 34 can include opening 34 constructed as a slit that extends along the tubular shape of the shroud.

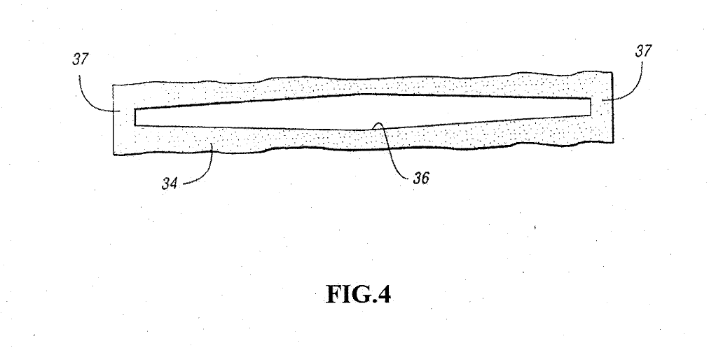

Referring to FIG. 4, shroud 34 can have opposite ends 37 between which slit-shaped opening 36 can have a varying size which facilitates distribution of the vapor and uniform deposition of the semiconductor layer. More specifically, slit-shaped opening 36 can have smaller size adjacent the ends 37 where the carrier gas and semiconductor material are introduced. Furthermore, slit-shaped opening 36 can have a larger size at the central more remote area from that introduction so as to provide the uniform deposition. To provide good distribution of the semiconductor material, it may be desirable to provide the interior of the tubular permeable member 24 with a suitable diverter that provides a uniform passage of the vapor outwardly along the length of the tubular permeable member and then along the length of the slit-shaped opening 36 of the shroud. Furthermore, shroud 34 can be made of a ceramic material that is most preferably mullite.

Shroud 34 can also advantageously reduce radiant heat transfer from hot tubular permeable member 24 to glass substrate 100. Substrate 100 can be heated during the processing to a temperature of about 100° to 650° C., 300° to 750° C., or 300° to 850° C., or any suitable value. More specifically, the amount of energy shroud 34 radiates to glass substrate 100 can be reduced because its outside surface temperature is lower than that of hot tubular permeable member 24. Mullite has an adequately low emissivity and is relatively strong and easy to fabricate. In addition, coatings can be provided to lower the emissivity of the outer surface of shroud 34 such as Al₂O₃ or Y₂O₃ .

In some embodiments, the length of the slit-shaped opening 36 of the shroud 34 can be selected to control the extent of the width of the deposited layer on glass substrate 100. Thus, the length of split-shaped opening 36 can be selected to be less than the width of the glass sheet substrate to provide a strip of the deposited layer. Such control can also minimize waste of the vapors. When the entire width of the substrate is to be covered, one can ideally make the length of the slit-shaped opening 36 equal to or slightly less or more than the width of the substrate such that the substantially all of the vapors are deposited onto the substrate during the deposition.

In providing efficient deposition, shroud 34 has been spaced from the conveyed glass sheet substrate a distance in the range of 0.5 to 3.0 centimeters. Greater spacings can be utilized that would require lower system pressures and would result in vapor waste due to overspraying. Furthermore, smaller spacing could cause problems due to thermal warpage of the glass sheet substrate during conveyance. Smaller spacing can also caused the desired substrate temperature for the process to be exceeded.

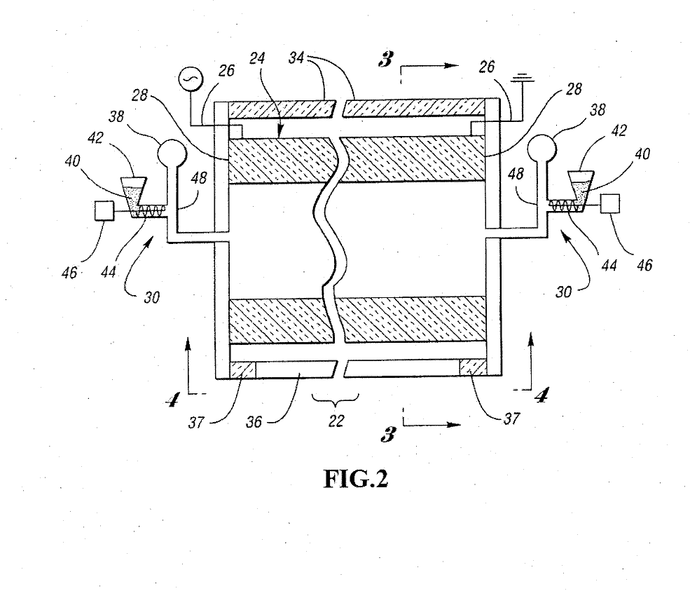

Referring to FIG. 2, material supply 30 introduces a carrier gas from source 38 and a semiconductor material as powder 40 from hopper 42 into one end 28 of tubular permeable member 24, and there is also another material supply 30 that likewise introduces a carrier gas and a semiconductor material as a powder into the other end 28 of the tubular permeable member 24. Thereby, there can be a good distribution of the carrier gas and entrained semiconductor powder along the entire length of tubular permeable member 24.

Each of material supplies 30 can include rotary screw 44 that receives semiconductor powder 40 from hopper 42 and can be rotatively driven by actuator 46. Delivery pipe 48 can extend from carrier gas source 38 to the adjacent end 28 of porous tubular member 24 in communication with rotary screw 44. Rotation of screw 44 at a controlled rate introduces semiconductor powder 40 into delivery pipe 48 so as to be entrained therein for flow into tubular permeable member 24 for the heating that provides the vapor.

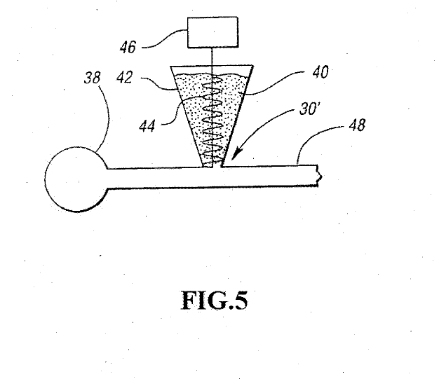

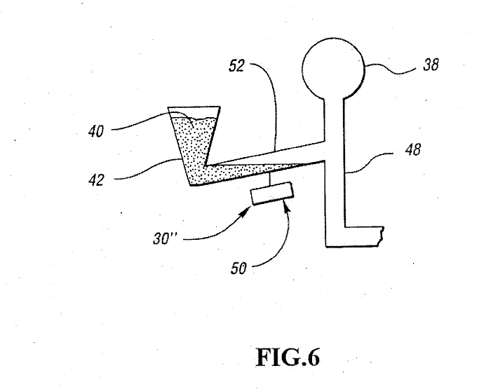

FIGS. 2, 5, and 6 respectively disclose different embodiments of the material supplies 30, 30′ and 30″. More specifically, material supply 30 illustrated in FIG. 2 has screw 44 rotated about a horizontal axis for introduction of semiconductor powder 40 into delivery pipe 48, while the FIG. 5 embodiment of material supply 30′ can include screw 44 rotated about a vertical axis for introduction of semiconductor powder 40 from hopper 42 into delivery pipe 48. With each of these screw embodiments of the material supplies, the amount of semiconductor material introduced as a powder can be accurately controlled by the rate of screw rotation. Furthermore, the FIG. 6 embodiment of material supply 30″ can include vibratory feeder 50 having inclined passage 52 extending upwardly from hopper 42 to delivery pipe 48. Operation of vibratory feeder 50 causes vibration of semiconductor powder 40 which moves it upwardly along inclined passage 52 to delivery pipe 48 for flow as an entrained powder into tubular permeable member 24.

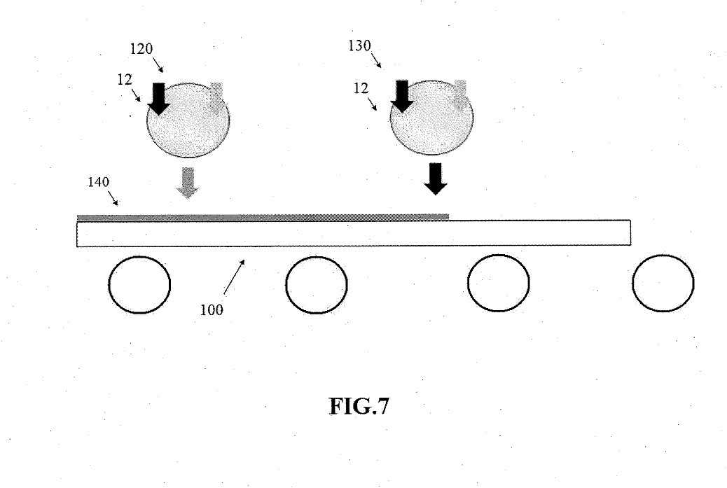

In some embodiments, the deposition of a semiconductor layer of photovoltaic device, such as a buffer layer of CIGS modules, can be a two step VTD process. Referring to FIG. 7, the deposition system can include two or more apparatuses 12. For deposition of a buffer layer of CIGS modules, VTD of an indium chalcogenide or zinc chalcogenide can be combined to grade the buffer layer in composition and bandgap via both metal and chalcogenide content. VTD of an indium chalcogenide or zinc chalcogenide can be combined in one apparatus 12 or performed by different apparatuses to deposit graded bandgap buffer layer 140 on substrate 100. An indium chalcogenide can be any suitable indium chalcogenide, including, for example, indium oxide (e.g., In₂O₃), indium sulfide (e.g., In₂S₃), or indium selenide (e.g., In₂Se₃), or combinations thereof. A zinc chalcogenide can be any suitable zinc chalcogenide, including, for example, zinc oxide (e.g., ZnO), zinc sulfide (e.g., ZnS), or zinc selenide (ZnSe), or combinations thereof.

Furthermore, in other embodiments, oxygen can be added to the transport gas or after the vapor exits the VTD source if only In₂S₃ (ZnS, In₂Se₃, ZnSe) is to be effluent from the distributor 24. In₂S₃ can be evaporated or otherwise vaporized in a partial oxygen ambient directing the vapor to the substrate without the use of a VTD source. In some embodiments, the deposition of a buffer layer of CIGS modules can be performed with a process evaporating from the elements In (Zn) and S in a partial oxygen ambient directing the vapor to the substrate without the use of a VTD source, such as reactive evaporation methods.

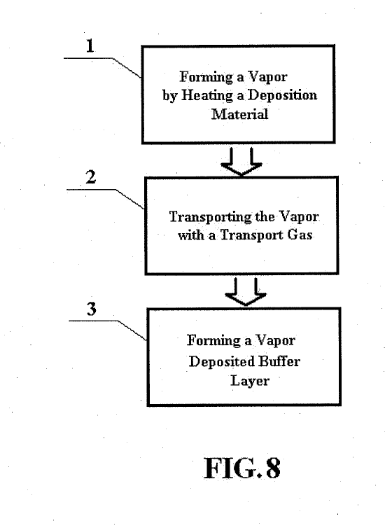

FIG. 8 is a graphical depiction of the steps in the process of forming the buffer layer. Step 1 can include forming a deposition material vapor by heating a deposition material. The deposition material can include a material selected from the group consisting of indium and zinc. Step 2 can include transporting the deposition material vapor with a transport gas. The deposition material vapor can be transported to a deposition chamber through a heated delivery pipe. Step 3 can include forming a buffer layer adjacent to a semiconductor absorber layer of a substrate. The vapor deposited buffer layer can include the deposition material selected from the group consisting of indium and zinc.

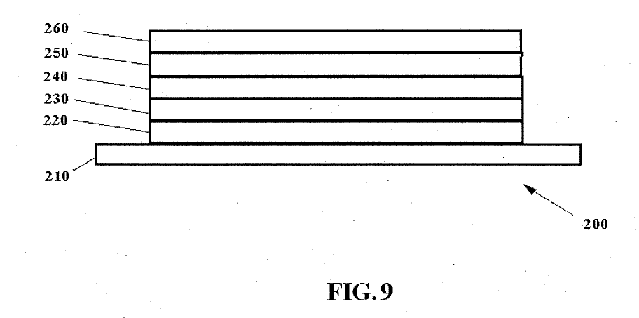

Referring to FIG. 9, as a product of the manufacturing process with a vapor transport deposition process discussed above, CIGS photovoltaic device 200 can include glass substrate 210, conducting layer 220, copper indium gallium diselenide absorber layer 230, buffer layer 240, and semiconductor window layer 250, and transparent conductive oxide layer 260. Glass substrate 310 can include sodium-containing glass. Transparent conductive oxide layer 320 can include tin oxide, sin oxide, or any other suitable transparent conductive oxide material. Semiconductor window layer 350 can include cadmium sulfide. Buffer layer 240 can include a metal chalcogenide, such as indium chalcogenide or zinc chalcogenide. Buffer layer 240 can include oxygen.

A number of embodiments of the invention have been described. Nevertheless, it will be understood that various modifications may be made without departing from the spirit and scope of the invention. It should also be understood that the appended drawings are not necessarily to scale, presenting a somewhat simplified representation of various preferred features illustrative of the basic principles of the invention.

What is claimed is:

1. A method of manufacturing a photovoltaic device, comprising:
forming a semiconductor absorber layer adjacent to a substrate, wherein the semiconductor absorber layer comprises copper indium gallium diselenide;
heating a deposition material to form a deposition material vapor, wherein the deposition material comprises a metal chalcogenide;
transporting the deposition material vapor to a deposition chamber with a transport gas through a delivery pipe; and
forming a buffer layer comprising the deposition material adjacent to the semiconductor absorber layer.

2. The method of claim 1, further comprising forming a conducting layer adjacent to the substrate before forming the semiconductor absorber layer adjacent to the substrate.

3. The method of claim 1, further comprising forming a transparent conductive oxide layer adjacent to the buffer layer.

4. The method of claim 3, further comprising forming a semiconductor window layer adjacent to the buffer layer before forming a transparent conductive oxide layer adjacent to the buffer layer.

5. The method of claim 1, wherein the deposition material comprises indium sulfide.

6. The method of claim 1, wherein the deposition material comprises an indium chalcogenide.

7. The method of claim 6, wherein the deposition material comprises indium selenide.

8. The method of claim 1, wherein the deposition material comprises zinc sulfide.

9. The method of claim 1, wherein the deposition material comprises a zinc chalcogenide.

10. The method of claim 9, wherein the deposition material comprises zinc selenide.

11. The method of any one of the preceding claims, wherein the step of heating the deposition material occurs in an environment comprising oxygen.

12. The method of claim 1, wherein the buffer layer further comprises oxygen.

13. The method of claim 1, wherein the step of heating the deposition material comprises heating the deposition material to a temperature greater than about 800 degrees C.

14. The method of claim 13, wherein the step of heating the deposition material comprises heating the deposition material to a temperature greater than about 1000 degrees C.

15. The method of claim 1, further comprising distributing the deposition material vapor evenly over the width of the substrate.

16. The method of claim 1, further comprising mixing the deposition material vapor and the transport gas to facilitate the reaction between the vapor and the transport gas before the vapor exits the distributor.

17. The method of claim 1, further comprising mixing the deposition material vapor and the transport gas to facilitate the reaction between the vapor and the transport gas after the vapor exits the distributor.

18. The method of claim 1, further comprising heating the delivery pipe.

19. The method of claim 1, wherein the transport gas comprises helium.

20. A vapor transport deposition system for manufacturing a photovoltaic device, comprising
a deposition material source comprising a deposition material including a material selected from the group consisting of indium and zinc;
a heater to heat the deposition material into a deposition material vapor;
a structure comprising a substrate, a conducting layer, and a semiconductor absorber layer comprising copper indium gallium diselenide;
a transport gas source which transports the deposition material vapor; and
a delivery pipe which delivers the transport gas and deposition material vapor to a position adjacent to the structure, resulting in the deposition material vapor being deposited adjacent to the semiconductor absorber layer to form a buffer layer.

21. The system of claim 20, wherein the delivery pipe is configured to mix the vapor and the transport gas and further facilitate the reaction between the vapor and the transport gas.

22. The system of claim 20, further comprising a distributor in the deposition chamber for evenly distributing the vapor over the width of the substrate.

23. The system of claim 22, wherein the distributor is configured to mix the vapor and the transport gas and further facilitate the reaction between the vapor and the transport gas.

24. The system of claim 22, further comprising a conveyor for conveying a substrate adjacent to the distributor for deposition of the vapor as a layer on the substrate.

25. The system of claim 20, wherein the transport gas comprises oxygen.

26. The system of claim 20, wherein the transport gas comprises a mixture of helium and oxygen.

27. A method of depositing a material on a substrate comprising:
heating a deposition material to form a deposition material vapor, wherein the deposition material comprises a material selected from the group consisting of indium and zinc;
transporting the deposition material vapor to a deposition chamber with a transport gas through a delivery pipe; and
forming a layer comprising the deposition material adjacent to the substrate.

28. The method of claim 27, wherein the deposition material comprises indium sulfide.

29. The method of claim 27, wherein the deposition material comprises an indium chalcogenide.

30. The method of claim 29, wherein the deposition material comprises indium selenide.

31. The method of claim 27, wherein the deposition material comprises zinc sulfide.

32. The method of claim 27, wherein the deposition material comprises a zinc chalcogenide.

33. The method of claim 32, wherein the deposition material comprises zinc selenide.

34. The method of claim 27, further comprising reacting the deposition material vapor with oxygen present in the deposition chamber environment.

35. A photovoltaic device comprising:
a substrate;
a semiconductor absorber layer comprising copper indium gallium diselenide adjacent to the substrate; and
a buffer layer comprising a metal chalcogenide adjacent to the semiconductor absorber layer.

36. The photovoltaic device of claim 35, further comprising a conducting layer between the substrate and the semiconductor absorber layer.

37. The photovoltaic device of claim 35, further comprising a transparent conductive oxide layer adjacent to the buffer layer.

38. The photovoltaic device of claim 37, further comprising a semiconductor window layer between the buffer layer and the transparent conductive oxide layer.

39. The photovoltaic device of claim 35, wherein the buffer layer comprises an indium chalcogenide.

40. The photovoltaic device of claim 35, wherein the buffer layer comprises a zinc chalcogenide.

41. The photovoltaic device of claim 35, wherein the buffer layer further comprises oxygen.
